(19) United States
(12) Patent Application Publication
(10) Pub. No.: US 2012/0097223 A1
(43) Pub. Date: Apr. 26, 2012

(54) PHOTOVOLTAIC DEVICE ON POLARIZABLE MATERIALS

(75) Inventor: Yevgeni Preezant, Zoran (IL)

(73) Assignee: Even Or Technologies Ltd., Nahariya (IL)

(21) Appl. No.: 13/295,055

(22) Filed: Nov. 12, 2011

Related U.S. Application Data
(63) Continuation-in-part of application No. PCT/IL2010/000386, filed on May 13, 2010.
Application No. PCT/IL2010/000386 is a continuation-in-part of application No. PCT/IL2010/000351, filed on May 3, 2010.

(51) Int. Cl. H01L 31/06; H01L 31/115

(52) U.S. Cl. 136/253; 136/255

(57) ABSTRACT

The invention is a photovoltaic device configured as a sandwiched structure comprising a bulk region between a pair of collecting electrodes. The bulk region comprises an electric-field inducing component and a photoactive component. The photoactive component is in electric contact with the collecting electrodes to provide a continuous conduction path for photo-generated charge carriers between the electrodes. The electric-field inducing component is adapted to provide a permanent electric field having high electric strength in the entire inter-electrode region, thereby inducing an electric field in the photoactive component. The electric-field inducing component does not participate in transport of the photo-generated charge carriers. The field inducing component can be comprised of a material that retains sustained polarization or a material that comprises and sustains a spatial distribution of electrical charges, or it can be comprised of both types of materials.

### CROSS REFERENCE TO RELATED APPLICATIONS

This application is a continuation in part of PCT application Ser. No. PCT/IL2010/000351, filed on May 3, 2010, and PCT application Ser. No. PCT/IL2010/000386, filed on May 13, 2010.

### FIELD OF THE INVENTION

This invention relates to conversion of electromagnetic radiation into electrical energy. More particularly the invention refers to photovoltaic or so-called solar cells that contain a photoactive component capable of converting light directly into electricity by the photovoltaic effect.

### BACKGROUND OF THE INVENTION

Among the requirements a solar cell should comply with is sufficient optical depth, sufficient power conversion efficiency and sufficient external quantum efficiency. Accordingly many efforts are invested by designers of photovoltaic cells to improve these parameters. Traditional semiconductor solar cells employ p-n junctions for separating photo-generated electron-hole pairs by virtue of a built-in electrical field at the depletion region near the metallurgical junction. Unfortunately the depth of the depletion region is limited due to fundamental physical limitation so p-n junction devices have limited optical depth. More advanced solar cells employ pin-junctions instead of p-n junctions to increase the optical depth, however manufacturing of solar cell pin-junctions is much more complicated.

In U.S. Pat. No. 4,435,610 is described a semiconductor solar cell employing a so-called “induced junction”. The “induced junction” is a depleted region arranged in a p-type crystalline silicone by deploying corona-charged electrets on one of the collecting electrodes outside of the bulk region where the photo effect occurs. An intrinsic disadvantage of this cell is diminishing of the electrical field produced by the electrets due to screening caused by the conducting collecting electrode which separates the depleted region from the bulk region confined by the electrodes. Due to screening, the “induced junction” enhances the power conversion efficiency and external quantum efficiency only to limited extent. Furthermore, since this solar cell employs crystalline silicon as the photo active material, its manufacturing cost is high due to the significant cost of production of crystalline silicon of a high degree of purity. This is a common problem in the manufacture of crystalline semiconductor solar cells that inhibits their wide use.

There exists also a large variety of solar cells based on amorphous inorganic materials such as amorphous silicon (a-Si and c-Si), CIGS (Cu/In/Ga/Se) thin film solar cells and a large variety of hetero junction solar cells, e.g. ZnO/c-Si cell. The principle of operation of these cells is identical to that of crystalline cells: namely, production of electrical energy by photo generated charge carriers that are separated due to the electric field present in the vicinity of the metallurgical junction between two materials. Therefore they have the same disadvantages as cells produced from crystalline materials, i.e. Limited optical depth due to limited size of depletion region, low (˜10⁴-10⁵ V/cm) fields inside the depletion region, low charge carrier mobility, and large recombination rates. The only advantage of the amorphous cells over the crystalline ones is the low manufacturing cost.

Development of semi conducting polymeric materials has led to a new type of solar cells—bulk-hetero junction solar cells. The photoactive material in this type of cell is a mixture of two semi conducting polymers (or a mixture of polymer with inorganic material) with different electron affinity. The separation of ,photo generated pairs occurs in these devices due to the difference of electrochemical potentials between the materials. The transport of free charge carriers is a field-driven transport, where the electrical field is produced by the difference of electrochemical potentials of the collecting contacts. Characteristic value of the field in these devices is electrical strength of 10⁴-10⁵ V/cm, which is insufficient for complete separation of initial excitations and for preventing recombination of the charge carriers. Consequently, although the solar cells made of amorphous materials are much cheaper than the cells made of crystalline materials, nevertheless their disadvantage is limited power conversion efficiency, which is ˜3-5% for polymeric materials as compared with ˜10-13% for inorganic materials. The reason for the low power conversion efficiency is morphological disorders in the amorphous material, which produce trapping sites for charge carriers. Trapping renders the transport of carriers less efficient and facilitates carrier losses during recombination.

A possible remedy to overcome the above disadvantage of amorphous materials would be providing a strong electric field inside the cell. It has been known for a long time from xerographics discharge experiments with a wide variety of amorphous materials that the quantum efficiency of photogeneration increases with increasing magnitude of the externally applied electrical field. For example for a-Si photogeneration efficiency increases from ˜0.1 at fields with strength lower than 10⁴ V/cm up to 1 at fields with strength of order 10⁶ V/cm. Also it is known that mobility of the charge carriers increases upon applying the electrical field and the mobility increases with increasing field strength. Nevertheless it is not known to widely use this phenomenon for improving efficiency of solar cells despite the existence of a few reports on attempts to introduce a built-in electric field into polymeric solar cell devices.

In one case [“Effect of Molecular Orientation on Photovoltaic Efficiency and Carrier Transport in a New Semiconducting Polymer” V. Kazukauskas et. al. ACTA PHYSICA POLONICA A, Vol. 113 (No. 3), pp. 1009-1012 (2008)] new functionalized soluble poly(p-phenylene vinylene) derivative bearing polarizable radicals was used as an active layer in a photovoltaic cell. Prior to operation the device was exposed to a dc electrical field having strength of about ˜10⁵ V/cm to align the polarizable moieties. The external quantum efficiency of this device was found higher by 1.5-2 times in comparison with the same device which was not exposed to polarization by the electrical field. Unfortunately, the quantum efficiency of this device was not compared with the efficiency of similar device based on original (non-functionalized) poly(p-phenylene vinylene); therefore it can not be concluded that the sole reason for improving the quantum efficiency is associated with the electrical field, since changing of molecular structure. of the polymer may deteriorate the performance of the device.

Another article [“Nanodipole photovoltaics” Diana Shvydka, V. G. Karpov Appl. Phys. Lett. Vol. 92, 053507 (2008)] suggests mixing of a photoactive polymer (host matrix) with permanent dipole bearing elongated CdS nano-crystals (guest component) oriented by virtue of poling the external dc field. The CdS crystals are supposed to create the field with strength of about 3×10⁴ V/cm in order to facilitate the separation of photo-generated pairs. Unfortunately this strength of electric field is insufficient for effective separation of charge carriers and for preventing their recombination

Also known in the prior art are attempts to use the internal electric field existing in ferroelectric materials for photovoltaic devices. One example is disclosed in U.S. Pat. No. 4,160,927. To the best of the knowledge of the inventor, all work that is similar to that disclosed in this patent exploit a well-known anomalous photovoltaic effect that has been studied since the early 1970s and all have the same drawback, i.e. despite high output voltage achieved with photovoltaic devices based on ferroelectrics, the output current is extremely low due to high internal resistance of the ferroelectric materials.

In all cases in which the material in which photo-activity and transport of charge carriers takes place is not separated from the material that generates the electric field the result will be limited efficiency of the photovoltaic device.

It is a purpose of the present invention to provide a new structure for photovoltaic devices that overcomes the drawback of the prior art by providing physical separation of the material in which photo-activity and transport of charge carriers takes place from the electric field inducing material.

It is a another purpose of the present invention to provide new and improved photovoltaic devices employing amorphous photoactive materials having improved performance over prior art devices in terms of optical depth, power conversion efficiency and quantum efficiency.

It is another purpose of the present invention to provide new and improved photovoltaic devices that are inexpensive, simple and convenient to manufacture.

Further purposes and advantages of this invention will appear as the description proceeds.

### SUMMARY OF THE INVENTION

The invention is a photovoltaic device configured as a sandwiched structure. The device comprises a bulk region between a pair of collecting electrodes. The bulk region comprises a matrix portion and a host portion. Either the matrix portion or the host portion is comprised of an electric-field inducing component and the remainder of the bulk region is comprised of a photoactive component. The photoactive component is in electric contact with both of the collecting electrodes to provide a continuous conduction path for photo-generated charge carriers between the electrodes. The electric-field inducing component does not participate in transport of the photo-generated charge carriers and it is adapted to provide a permanent electric field having high electric strength in the entire inter-electrode region, thereby inducing an electric field in the photoactive component.

When a load is electrically connected to the collecting electrodes and the photoactive component is illuminated and/or irradiated, an electrical current flows through the photovoltaic device of the invention. The photoactive component can be illuminated and/or irradiated by at least one of the following: electro-magnetic radiation; the sun; decay of the nucleus of a radioactive material; and a photo-chemical reaction.

In embodiments of the photovoltaic device the bulk region is provided with a plurality of through going channels that are filled with the host portion. In some embodiments the channels are rectilinear and parallel to each other. In other embodiments the channels are curvilinear and are chaotically distributed within the bulk region. In the latter embodiments, although an individual channel may not pass entirely through the bulk region, it will intersect another channel or channels such that there is a continuous open path from the end of a given channel that is open on one of the electrodes to the other electrode.

The collecting electrodes are made from electrically conductive material selected from the group comprising: metals, semiconductors, conductive polymers, conductive oxides and their combinations.

The photoactive component of the photovoltaic device of the invention can be made from photoactive material selected from the group comprising: semiconductors of group IV of the periodic table, group III-V semiconductors, group II-VI semiconductors, photoactive polymers and their combinations.

In embodiments of the photovoltaic device the electric-field inducing components are comprised of materials that retain sustained polarization. In these embodiments the material of which the field inducing components are comprised can be selected from the group comprising: ferroelectric materials and polymeric ferroelectrics.

In embodiments of the photovoltaic device the electric-field inducing components comprise a plurality of dipole moieties that are capable of being polarized and retaining orientation of the induced polarization. In these embodiments the dipole moieties can be selected from the group consisting of organic dielectric materials, inorganic dielectric materials, and their combinations. The inorganic dielectric materials can be selected from the group of materials having formula SiOₓ, SiNₓ, and their combinations.

In embodiments of the photovoltaic device the electric-field inducing components comprise a material capable of retaining spatial charge distribution.

In embodiments of the photovoltaic device of the invention the photoactive component is a slab of photoactive material and the field-inducing component consists of a plurality of isolated deposits of insulating material or of thin porous insulating layers. The deposits or layers comprise “frozen” electrical charges and are distributed on the surfaces of the slab of photoactive material adjacent to the electrodes.

In embodiments of the photovoltaic device of the invention the photoactive component is a slab of photoactive material and the field-inducing component comprises at least one electrically conductive grid having a plurality of openings. The grid is located between a surface of the slab of photoactive material and at least one collecting electrode and is electrically insulated from the photoactive material and from the adjacent collecting electrode.

All the above and other characteristics and advantages of the invention will be further understood through the following illustrative and non-limitative description of embodiments thereof, with reference to the appended drawings. In the drawings the same numerals are sometimes used to indicate the same elements in different drawings.

### BRIEF DESCRIPTION OF THE DRAWINGS

FIG. 1 is an exploded perspective view of the photovoltaic cell according to one embodiment of the invention;

FIG. 2a to FIG. 2g schematically illustrate the steps of a method for manufacturing the cell shown in FIG. 1;

FIG. 3a to FIG. 3e schematically illustrate the steps of an alternative method for manufacturing the cell shown in FIG. 1;

FIG. 4 is an exploded perspective view of a photovoltaic cell according to another embodiment of the invention;

FIG. 5a to FIG. 5f schematically illustrate the steps of a method of manufacturing the cell shown in FIG. 4;

FIG. 6a and FIG. 6b schematically illustrate a third embodiment of the photovoltaic device of the invention;

FIG. 7 schematically illustrates a fourth embodiment of the photovoltaic device of the invention;

FIG. 8a to FIG. 8d schematically illustrate a manufacturing path for the device shown in FIG. 7 that is useful with inorganic photoactive material;

FIG. 9a to FIG. 9e schematically illustrate a manufacturing path for the device shown in FIG. 7 that is useful with polymeric photoactive material or photoactive material that is deposited from solution or melted phase deposition;

FIG. 10 is an exploded view that schematically shows the fifth embodiment of the photovoltaic device of the invention;

FIG. 11a to FIG. 11d schematically show an example of a manufacturing path for fabricating the grids of the device of FIG. 10; and

FIG. 12a to FIG. 12d schematically show an example of a manufacturing path for fabricating the device of FIG. 10.

### DETAILED DESCRIPTION OF EMBODIMENTS OF THE INVENTION

This invention is a new structure for photovoltaic devices that contain a photoactive component capable of converting radiation directly into electricity by the photovoltaic effect. The most common type of radiation used to excite photovoltaic devices is optical radiation. When the source of the radiation is the sun, the photovoltaic devices are commonly called solar cells. However optical radiation is not the only type of radiation capable of exciting photoactive material. In applications demanding long-life duration and or in which the amount of optical radiation is limited or non-existent, e.g. under the surface of the sea or earth or at night, then devices having identical operational principles may be powered by radiation from the radioactive decay of the nucleus of material embedded within or placed alongside the device. In other embodiments, the source of excitation can be a photo-chemical reaction taking place inside or close to the photoactive material. The structure of the invention can be used to construct photovoltaic devices that are activated by any of these methods of excitation.

The photovoltaic devices of the invention have improved performance over prior art devices in terms of optical depth, power conversion efficiency and quantum efficiency. Also described are methods of manufacturing these photovoltaic devices. The objectives of the invention are achieved by providing within the photovoltaic device a built-in, permanent electric field having high electrical strength throughout the device, i.e. the built-in electric field is present in the whole inter-electrode space and is not limited to some region such as the depletion region in p-n junction devices.

The main feature of the invention is that the bulk region between a pair of collecting electrodes has a structure comprising a host portion accommodated within a matrix portion; wherein either the matrix portion or the host portion consists of a non-conductive, electrical field inducing component and the other portion consists of a semi conductive photoactive component. Additionally the photoactive component is deployed in the bulk region in such a manner that it is always in electric contact with both collecting electrodes to provide a continuous conduction path between them.

Herein, the term “field inducing component” refers to a material which either naturally possesses a permanent electric field or in which a permanent electric field has been induced. The “field inducing component” induces an electric field in the photoactive component, thereby reducing recombination of the charge carriers and improving their mobility through the photoactive material to the collecting electrodes.

Due to the high strength electrical field induced by the field inducing component in the photoactive component, it is expected that quantum and power-conversion efficiency of the photoactive component will improve irrespective of the kind of photoactive material used. A further positive aspect associated with exposing the bulk portion to a built-in electric field with high strength is the possibility of building a photovoltaic device wherein the active region of the photoactive material has a large optical depth.

Since the induced permanent electrical field improves the performance of the photoelectric device of the invention irrespective of the type of semi conductive photoactive material used, the present invention is not limited merely to photovoltaic cells based on amorphous semiconductor materials, which are cheap, widespread, environmental-friendly and simple in manufacturing. The present invention can also be implemented in photovoltaic cells based on crystalline materials suitable for conversion of electromagnetic radiation into electrical energy.

Before describing the photovoltaic devices of the invention the major components are now defined. These components include two collecting electrodes, a field inducing component, and a photoactive component.

The collecting electrodes are two conducting members arranged at both sides of the photovoltaic device. Their function is to collect the charges produced by photo generation in the photoactive component and to deliver the charges outside of the device to an electric load. Each of the collecting electrodes collects only one type of charge carrier. The electrode collecting negatively charged carriers is called the anode, while the electrode collecting positively charged carriers is called the cathode. The electrodes can be made of any electrically conducting material, e.g. metals, semiconductors, conducting polymers such as PEDOT/PSS or conducting oxides such as ZnO or Indium-Tin Oxide (ITO). The collecting electrodes may be transparent or opaque.

The field inducing component is a spatial structure or set of spatial structures that induces an electrical field inside the device. The field inducing component can be comprised of a material that retains sustained polarization or a material that comprises and sustains a spatial distribution of electrical charges, or it can be comprised of both types of materials. The field inducing component can be transparent or opaque. The field inducing component is distributed in the bulk region between the electrodes in a manner that allows direct electric contact between the photoactive material and the collecting electrodes while preventing the field inducing component from participating in the transport of photo-generated carriers.

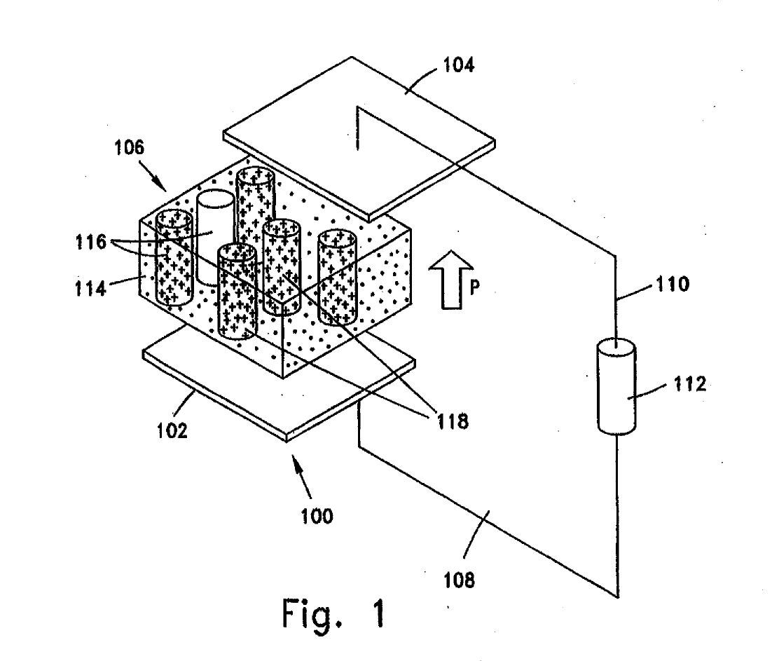

Examples of suitable materials for a field inducing component that retains sustained polarization include a ferroelectric material, e.g. barium titanate (BaTiO₃) and lead zirconate titanate (PZT) or polymeric ferroelectrics such as polyvinylidene difluoride (PVDF) and polytrifluoroethylene (PTrFE). In general the polarization may be directed in an arbitrary direction but the preferred direction is perpendicular to the electrode surfaces. The first and second embodiments of the invention that are described with respect to FIG. 1 to FIG. 5F herein below comprise field inducing components that are comprised of materials that retain sustained polarization.

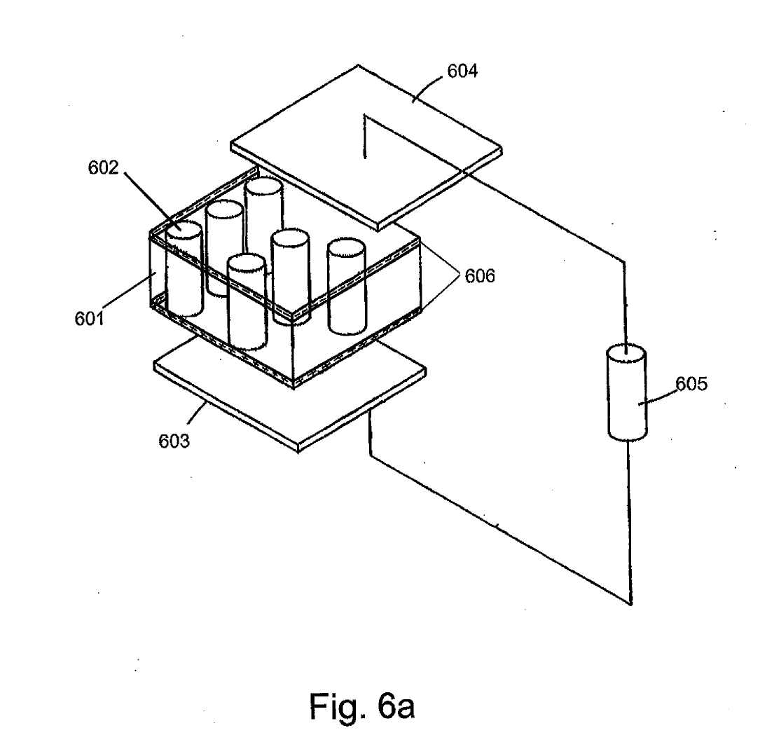

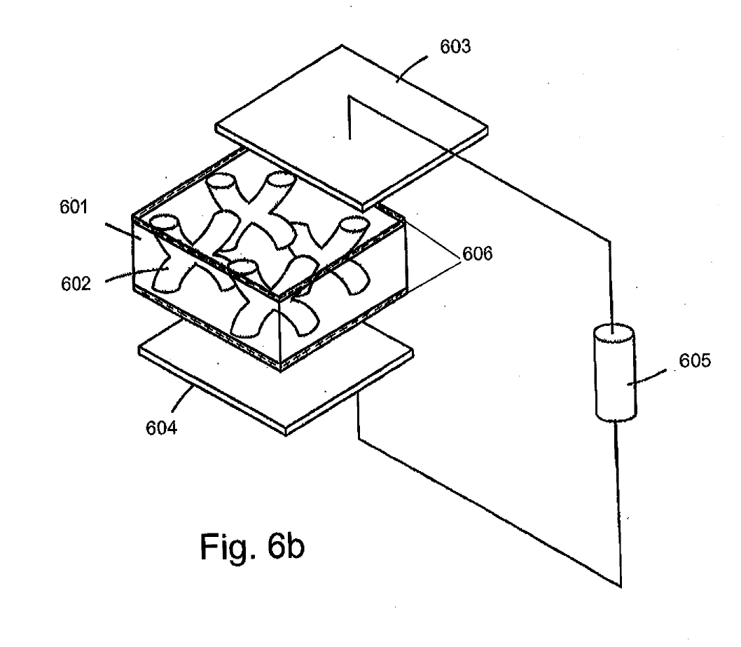

A field inducing component that sustains a spatial charge distribution could be made from any material capable of preserving the charge distribution for a long time. Examples of such materials are: inorganic dielectrics, e.g. SiOₓ, SiNₓ and organic dielectrics, e.g. poly-silane resins or poly(methyl methacrylate) (PMMA). An example of hybrid structure suitable for fabrication of the field inducing component is a grid of conductors covered with insulating material. The third, fourth, and fifth embodiments of the invention that are described with respect to FIG. 6a to FIG. 12d herein below comprise field inducing components comprised of materials that sustain a spatial charge distribution.

The photoactive component is the component responsible for photo-generation of free charge carriers and transport of the charge carriers. This component should be arranged between the collecting electrodes in such a manner that it is in direct electrical contact with both collecting electrodes to provide continuous conduction paths between the two electrodes.

The photoactive component consists of a photoactive material or any combination of such materials. A non-limiting list of photoactive materials comprises, for example: semiconductors of group IV of the periodic table, e.g. Si and Ge; group III-V semiconductors, e.g. GaAs or InP; group II-VI semiconductors, e.g. CdTe,CdHgTe; and photoactive polymers and their mixtures, e.g, P3HT, C60, MEH-PPV and their derivatives.

During operation of the device the collecting electrodes are electrically connected via a load. Electrical current flows through the load and through the device when the photoactive component is illuminated and/or irradiated. The illumination/radiation causes photo generation of charge carrier pairs in the photoactive component. The charge carriers separate and move to the respective collecting electrodes. The charge carriers are accelerated by the electric field induced by the field inducing component and b_{y} the difference of electrochemical potential between the collecting electrodes. The illumination/radiation can take place through the field-inducing component or through one or both of the collecting electrodes. Also the illumination and/or irradiation can be provided by a photochemical process taking place within the device or from a radiation source which is located inside the device.

A first embodiment of the photovoltaic device of the present invention is shown in FIG. 1. Photovoltaic device 100 comprises a pair of collecting electrodes 102, 104 and a bulk region 106 confined there between. Each of the collecting electrodes is connected by a respective wire 108, 110 to a resistive load 112. The bulk region is comprised of a matrix portion 114 in which are distributed a plurality of discrete parallel tubular-shaped channels 116. Each of the channels 116 extends through the matrix portion 114 and is entirely filled with a host portion 118. In FIG. 1, for the sake of clarity one of the channels 116 is shown empty, while the rest of the channels are shown filled with the host portion 118 configured as elongate members, e.g. rods, bars whose cross-sectional shape matches the cross-sectional shape of the channels 116.

In this embodiment of the invention the matrix portion 114 functions as a field inducing component responsible for persistent polarization directed along the direction indicated by arrow P. In order to impart the field inducing ability to matrix portion 114 it can be made of any of the ferroelectric materials mentioned above.

In this embodiment the host portion 118 within the channels 116 functions as a photoactive component. When device 100 is manufactured a conductive path between the two electrodes 102, 104 is established by providing direct electric contact between the host portion 118 and both collecting electrodes. The host portion 118 may consist of a single homogeneous photoactive material or of several photoactive materials selected from the above mentioned list. If host portion 118 consists of different photoactive materials they may be present as a homogeneous mixture or arranged in any spatial structure. For example, the host portion 118 may be configured as a cylindrical core coated with one or more annular cladding layers, as a super-lattice, or as an interpenetrating network of different photoactive materials.

For the embodiment shown in FIG. 1, the approximate thickness, i.e. the distance between collecting electrodes, of photovoltaic device 100 is about 0.5-5 microns. The lateral dimensions of photovoltaic device 100 are limited by manufacturing considerations and may vary from several millimeters up to several tens of centimeters. The diameter of the round cross-section of channels 116 is 10-100 nm and the distance between adjacent channels should be not less than their diameter. There is no limitation imposed on the cross-sectional shape of channels 116, which can be circular, oval, elliptical, hexagonal, rectangular or any other shape. The longitudinal axis of channels 116 should be oriented approximately perpendicularly to the planes of collecting electrodes 102,104.

It should be borne in mind however that it is not necessary that matrix portion 114 constitutes the field inducing component and that host portion 118 constitutes the photoactive component. In embodiments of the invention the opposite situation occurs, i.e. the host portion 118 constitutes the field inducing component and the matrix portion 114 constitutes the photoactive component. In these embodiments the field inducing component fills the channels 116, while the photoactive component forms the surrounding matrix portion 114. In this case the diameter of the channels 116 should be larger, than in the previous case.

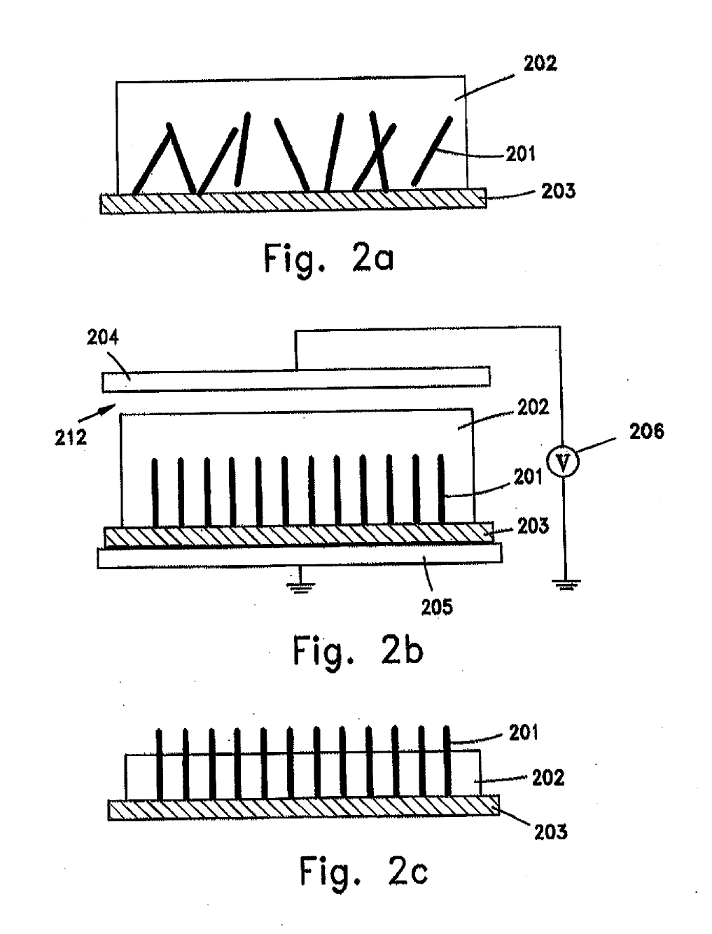

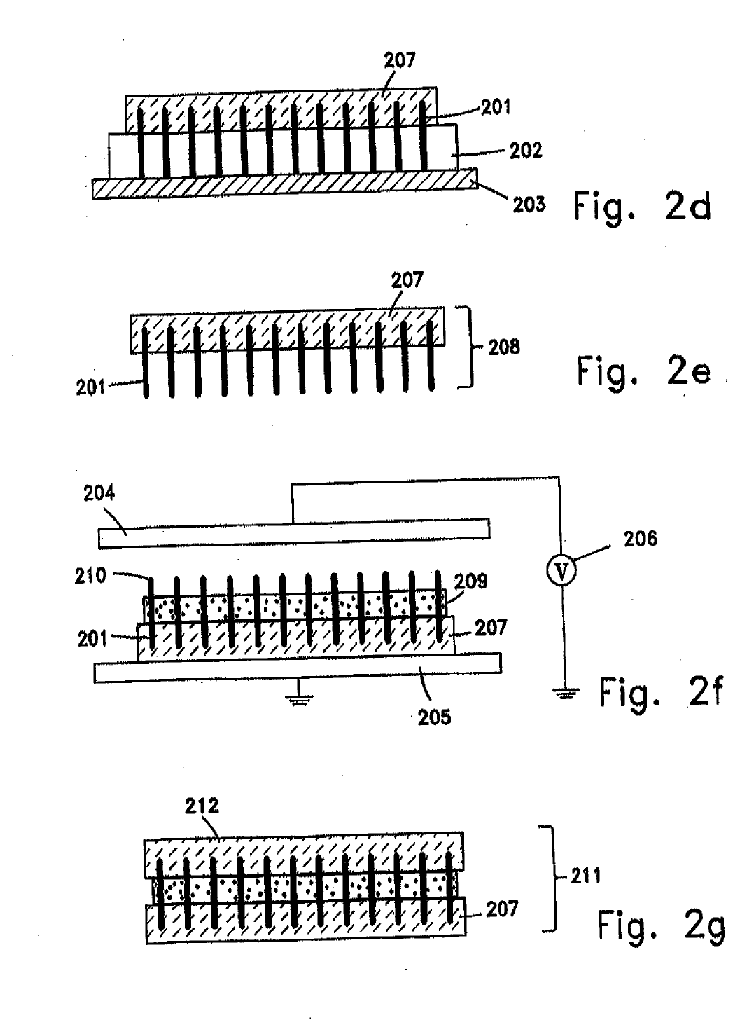

An example of a method for fabrication of photovoltaic device 100 having the structure shown in Fig.1 will now described with reference to FIG. 2a to FIG. 2g. In this example the host portion 118 constitutes the photoactive component and it is configured as a plurality of nanorods made of inorganic photoactive material. As used herein, the term “nanorod” generally refers to any elongated particle having an aspect ratio (length:width) 100:10 that is comprised of any of the conductive or semi conductive materials listed herein above. The length of the nanorods defines the thickness of device 100 and should be about 0.5-5 micron as prescribed above. The lateral dimensions should be about 10-100 nm. The nanorods are produced by any method known in the art, e.g. template-assisted deposition, free solution synthesis, or grown on a subtstrate by liquid or chemical vapor deposition. As already mentioned the nanorods can be made of homogeneous bulk materials or of more than one material arranged in homogeneous of arbitrary spatial structures.

In FIG. 2a the first step of the manufacturing sequence is shown. This step comprises embedding a photoactive component, configured as a plurality of nanorods 201, into a melted dielectric polymer sacrificial matrix 202. Then the melted sacrificial matrix with the phothactive component is spread onto a sacrificial substrate 203 as a thin layer. Examples of a suitable dielectric polymer for the sacrificial matrix 202 are PMMA (Polymethylmethacrylate) or PVAI (Polyvinyl alcohol). Matrix 202 can be spread onto substrate 203, which can be made for example from polycarbonate, by any method known in the art, e.g. use of a doctor-blade or spin-coating.

The next step of the method is shown in FIG. 2b. This step comprises placing the substrate 203 with the melted matrix 202 spread onto it between a pair of auxiliary electrodes 204 and 205. A gap or a buffer layer 212 can be left between the auxiliary electrodes and the matrix. An electric field is then applied to the matrix 202 by a voltage source 206 electrically connected to the auxiliary electrodes. The electrical field aligns the nanorods substantially orthogonally to substrate 203. The voltage source 206 should be capable of creating a local electrical field having electrical strength of about 10⁶ V/cm within sacrificial matrix 202 sufficient for nanorod alignment. After the nanorods are aligned, the melted sacrificial matrix 202 is allowed to cool down and, after it solidifies, the voltage source 206 is turned off. The result of step 2b is a solid sacrificial polymer matrix 202 with aligned photoactive components inside it.

The next step is shown in FIG. 2c. It comprises dissolving the upper part of the sacrificial polymer matrix 202 to expose the upper ends of the nanorods 201.

In the next step, which is shown in FIG. 2d, a first collecting electrode 207 is deposited on the exposed ends of the nanorods 201 to ensure that reliable electrical contact is provided between the electrode 207 and the photoactive component. The electrode 207 can be metallic, e.g. Pt, Au, Al, or can be made from conductive ceramics, e.g. oxides such as ITO or ZnO. The electrode can be deposited by evaporation, by sputtering, by electroplating, by electrode-less deposition, by melting nano particles of a conductive material, by sol-gel deposition, or by any other deposition method that will ensure good electrical contact between the connecting electrode and the photoactive component.

The next step of the method comprises evacuation of the remaining portion of the sacrificial polymeric matrix 202 and of the sacrificial substrate 203 exposing the ends of the nanorods 201 opposite to those connected to electrode 207. The comb-like structure 208 that is obtained is shown in FIG. 2e. The removal of the sacrificial material can be accomplished by dissolving, burning or any other suitable method.

There are alternative methods for fabricating the comb-like structure 208 shown in FIG. 2e. One of these alternative methods starts with a commercially available sacrificial polymer track-etched or anodic alumina membrane of the type known in the art from filtration applications. The membrane should comprise straight pores that pass through it substantially perpendicularly to its surfaces. The pores are opened on both surfaces of the membrane. In the first step the collecting electrode is deposited on one of the membrane surfaces. The second step is deposition of photoactive material into the pores of the membrane. The photoactive material is deposited by any deposition method known in the art, e.g. chemical bath deposition, electro-deposition, sol-gel deposition. The process of producing structure 208 is concluded by removing the membrane by any appropriate method such as burning out or chemical etching. It should be born in mind that some of the steps of the method can be carried out in reverse order, i.e. the deposition of the collecting electrode may come after filling the pores of the sacrificial membrane with the photoactive material. The order in which these steps are carried out depends on the technological needs that stem from the properties of chosen photoactive and sacrificial material.

After the comb-like structure 208 has been manufactured, the step shown in FIG. 2f is carried out. In this step the space between the nanorods 201 in comb-like structure 208 is filled by a matrix 209 consisting of a ferroelectric material that possesses the necessary properties to act as the field-inducing component of the photovoltaic device. This step can be carried out by any of a number of methods. For example, BaTiO₃ can be deposited by use of the sol-gel method on the comb-like structure with subsequent annealing. Instead of ceramic ferroelectric material a polymeric material, e.g. PVDF or polycarbonate or other polymer can be deposited by spin-coating from solution and dried. The nanorods 201 should be surrounded by the matrix however at least the tips 210 of their free ends should remain uncovered by the deposited material in order to enable electric contact with a second collecting electrode, which will be deposited during the next step. During this step the structure, which comprises a first electrode 207, a matrix 209 and nanorods 201 embedded in matrix 209, is placed between auxiliary electrodes 204, 205, which are connected to the voltage source 206. The structure is exposed to an electrical field in the manner described above with reference to FIG. 2b, thereby polarizing the material of the field inducing component. After the field inducing component has been polarized the external voltage source 206 and auxiliary electrodes 204,205 are removed.

In the final step, which is shown in FIG. 2g, the manufacturing sequence is completed by deposition of a second collecting electrode 212 on the side of the structure opposite the first collecting electrode 207. The second collecting electrode is deposited by a method similar to that used to deposit the first electrode 207, i.e. by any of the methods mentioned in connection with FIG. 2d, such that reliable electrical contact is provided between the second electrode 212 and the photoactive component.

At the end of the process there is obtained photovoltaic device 211, whose structure comprises a bulk region confined between a pair of opposite collecting electrodes. The bulk region is comprised of a matrix portion made of material that functions as an electric field inducing component. The matrix portion accommodates inside it a host portion, which is distributed within the matrix portion and is made of material that functions as a photoactive component.

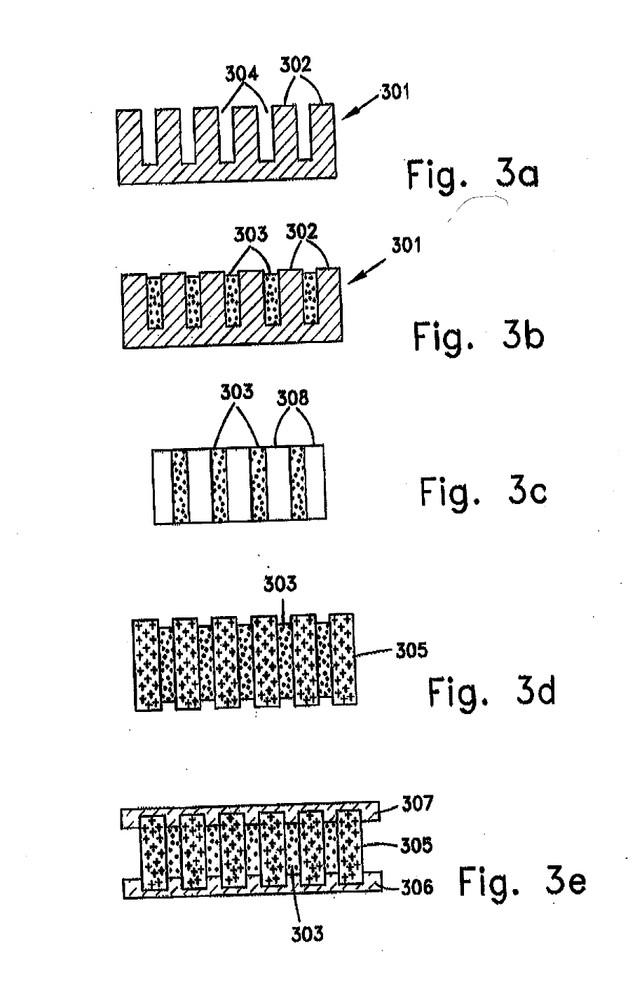

An alternative method for manufacturing the photovoltaic device of the present invention will now be described with reference to FIG. 3a to FIG. 3e. In contrast to the previously described method that starts with preparation of the photoactive component, this method starts with preparation .of the field-inducing component. As seen in FIG. 3a, in the first step a sacrificial polymer template 301 comprising a plurality of nano-pillars 302 that are oriented substantially parallel to each other and perpendicularly to the lateral faces is used. The nano-pillars are surrounded by nano-voids 304 that comprise the space between them. The template could be, for example, a polymeric negative replica of a commercially-available anodic alumina porous membrane. The template 301 serves as a medium for deposition of a ferroelectric material 303 into nano-voids 304, as shown in FIG. 3b. Any of the ferroelectric inorganic materials described herein above can be deposited, for example, BaTiO₃. The deposition can be accomplished by, for example, sol-gel deposition. Following deposition of the ferroelectric material, the template 301 is annealed. During the annealing process the sacrificial material, i.e. the nano-pillars 302, is burned away. As a result of the annealing step there is obtained a field inducing component configured as the spatial structure comprised membrane of ferroelectric material 303 with through-going holes 308 shown in FIG. 3c.

After the template 301 has been burned away, the spatial structure comprised of columns of ferroelectric material 303 shown in FIG. 3c is exposed to an external electrical field to polarize the material of the field inducing component. This is carried out with the use of auxiliary electrodes as described herein above with reference to FIG. 2b and FIG. 2f.

In the next step, which is shown in FIG. 3d, The through-going holes 308 in the membrane of ferroelectric material 303 of the field inducing component are filled with a photoactive component 305. This can be accomplished by any method known in the art that is appropriate for use with the material chosen for the photoactive component, e.g. electro deposition, sol-gel deposition, or dipping.

In the final step, shown in FIG. 3e, part of the ferroelectric material 303 is removed to expose the ends of the photoactive component 305 and a pair of collecting electrodes 306 and 307 is deposited at opposite sides of the structure by one of the methods described herein above with reference to FIG. 2d. As in the previously described method, one of the collecting electrodes may be deposited before the field inducing component structure is filled with the photoactive material. The order of the steps of the method depends on the technological needs that stem from the properties of the chosen materials.

At the end of this manufacturing process a photovoltaic device whose structure consists of a bulk region confined between a pair of opposite collecting electrodes is obtained. The bulk region comprises a matrix portion comprised of the field inducing component. The matrix portion accommodates inside it a host portion, distributed within the matrix portion and comprised of the photoactive component.

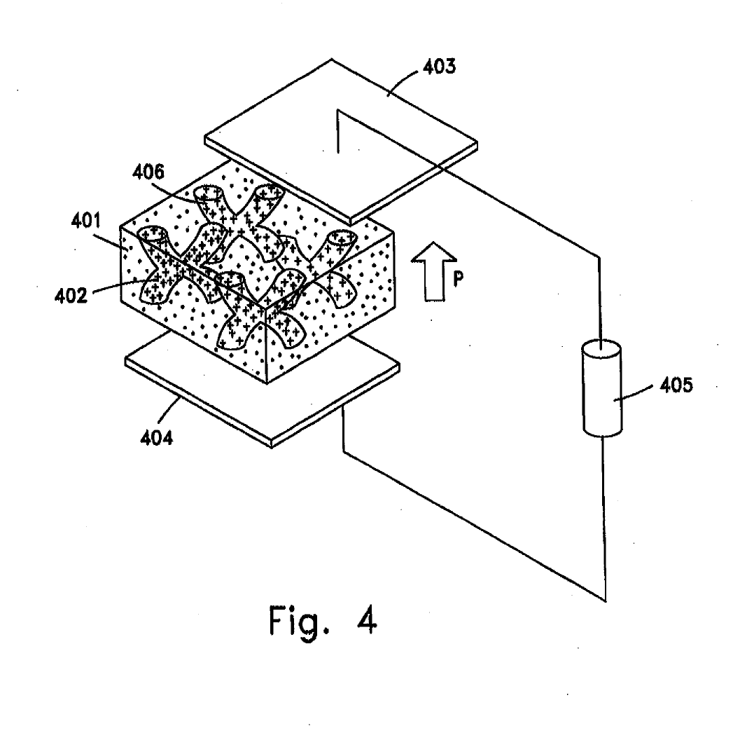

A second embodiment of the photovoltaic device of the invention is depicted in FIG. 4. The bulk region of the device consists of a matrix portion 401 constituted in this example by the field inducing component material. The matrix portion is made of a ferroelectric material, which is capable of retaining persistent polarization in the direction shown by arrow P. The matrix portion is provided with a plurality of channels 402 that pass through it and are open at opposite sides of the bulk region. Channels 402 are filled with a photoactive material 406 of the photoactive component. The bulk region is confined between a pair of opposite collecting electrodes 403 and 404. The collecting electrodes are electrically connected with a resistive load 405. In general the structure and dimensions of this device, as well as the materials of the photoactive component and the field inducing component are similar to those already described in connection with the previous embodiment. However in contrast to the previous embodiment the channels 402 in the matrix portion 401 are not directed parallel to each other and are not perpendicular to the collecting electrodes. As seen in FIG. 4, the channels 402 are shaped and oriented chaotically while passing from one side of matrix portion 401 to the other. The channels are interconnected such that, although an individual channel 402 may not pass entirely through the bulk region, it will connect to another channel or channels such that there is a continuous open path from the end of a given channel that is open on one of the electrodes 403,404 to the other electrode. By virtue of this provision the photoactive component is configured as a spatial net-like structure terminating at opposite sides of the bulk region.

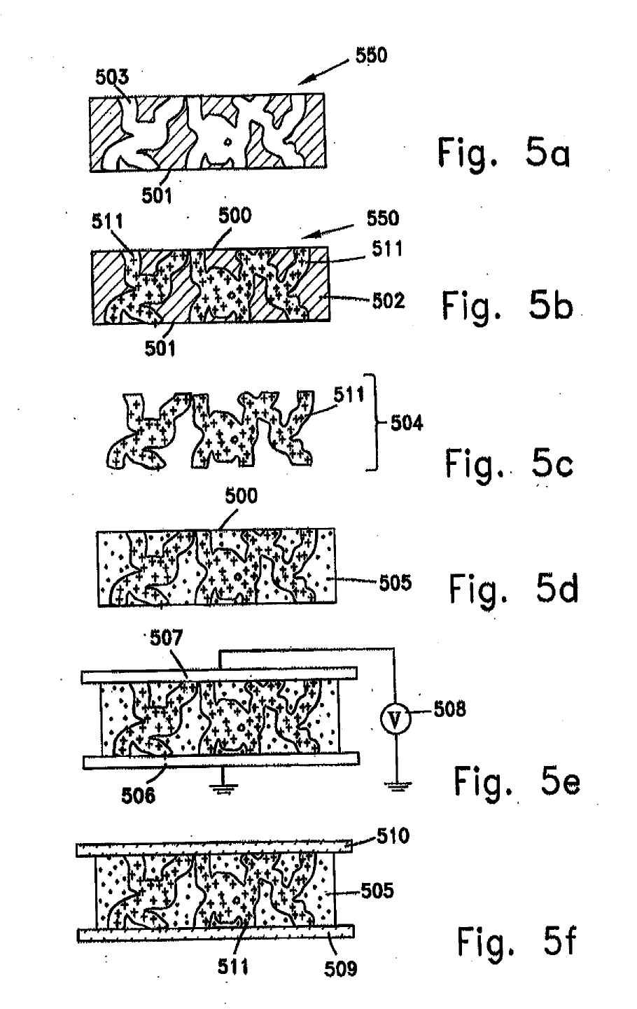

FIG. 5a to FIG. 5f schematically illustrate a method of manufacturing the photovoltaic device shown in FIG. 4. In this example the manufacturing sequence begins with creating the photoactive component.

In the first step, which is shown in FIG. 5a, a porous auxiliary structure 550 is provided. Polymeric membranes having the required characteristics are commercially available or can be produced by any of several methods known in the art. Auxiliary structure 550 is defined by opposing lateral faces 500, 501 between which is confined a bulk portion 502 having a plurality of interconnected channels or pores 503 chaotically distributed within the bulk portion. The channels are curvilinear and pass through bulk portion 502 in the sense that they are open at opposite lateral faces of the membrane such that fluid communication can be established between both faces, i.e. starting at the open end of any of the channels on one of the electrodes a path can be traced through the interior of the interconnected channels until the other electrode is reached. As shown in FIG. 5b, the channels of the membrane are filled with a photoactive inorganic material 511, which can be deposited into the pores 503 by an electrochemical, chemical or sol-gel method that is chosen to be compatible and to give optimal results with the specific material to be deposited.

In the next step the bulk portion of the sacrificial membrane is evacuated e.g. by dissolving, burning out, etching by acid or removing by any other method appropriate for use with the specific material of which the membrane is made and the photoactive material 511 that has been deposited into the pores 503. After the membrane has been evacuated there remains a free-standing lateral net-like structure 504 made of photoactive material 511. This structure is shown in FIG. 5c and it constitutes the photoactive component.

In the next step, which is shown in FIG. 5d, the free space of the spatial structure 504 surrounding the photoactive material 511 is filled with the material 505 of the field inducing component. An example of a suitable material that can be used for the field inducing component is an inorganic ferroelectric material, like BaTiO₃. Material 505 can be deposited by, for example, the sol-gel method with subsequent annealing. Alternatively the material 505 of the field inducing component can be comprised of a polymer, e.g. PVDF or polycarbonate, which can be deposited by spin-coating from. solution and dried. It is emphasized that deposition of the field inducing component material should be carried out in such a manner that direct electrical contact can be provided between the material 511 of the photoactive component and the collecting electrodes, which will be added during the next step of the procedure. Assuring that the ends of material 511 are exposed can be accomplished, for example, by dissolution or plasma etching of material 505 of the field inducing component at opposite sides of the structure.

In the next step, which is shown in FIG. 5e the material 505 of the field inducing component is polarized by exposing the whole structure to an external electric field produced by two auxiliary electrodes 506 and 507 connected to a voltage source 508. The voltage source 508 should be capable of producing a high-voltage electrical field having a local field strength of about 10⁵-10⁷ V/cm.

In the final step, shown in FIG. 5f, a pair of collecting electrodes 509 and 510 is deposited at opposite sides of the structure by any appropriate method as described above with reference to the previously described methods.

It should be born in mind that the deposition of one of the collecting electrodes may come before the filling of the pores 503 of the sacrificial membrane 550 with photoactive material 511 or before the filling of the photoactive component structure 504 by material 505 of the field inducing component or before the polarization of material 505. The order of the steps can easily be determined by experienced persons and will depend on the technological needs that stem from the properties of the chosen materials.

At the end of the manufacturing process described with respect to FIG. 5a to FIG. 5f there is obtained a photovoltaic device whose structure consists of a bulk region confined between a pair of collecting electrodes. The bulk region comprises a matrix portion comprised of the field inducing component. The matrix portion accommodates inside it a host portion, chaotically distributed within the matrix portion and comprised of the photoactive component.

The manufacturing procedure described with respect to FIG. 5a to FIG. 5f is also applicable mutatis mutandis for manufacture of a device having an “inverted structure”, i.e. a structure, in which the matrix portion is comprised of the photoactive component, while the host portion is comprised of the field inducing component. For this purpose instead of deposition of photoactive material 511 into the pores 503 of the sacrificial membrane 550, material 505 of the field inducing component would be deposited and subsequently the free space of the produced structure would be filled with photoactive material 511.

Another way of manufacturing the photovoltaic device shown in FIG. 4 is to prepare a porous ferroelectric membrane by sintering a mixture of ferroelectric powder with fine particle organic additives. Sintering will eliminate the organic additives producing a porous ferroelectric membrane similar to that shown in FIG. 5a. The channels left when the organic additives are eliminated are then filled with photoactive material and the steps shown in FIGS. 5e and 5f are carried out to complete the manufacturing process.

In an alternative method the device shown in FIG. 4 could be produced by a one-step method consisting of sintering a mixture comprised of powders of ferroelectric photoactive materials.

A third embodiment of the photovoltaic device of the invention is schematically illustrated in FIG. 6a and FIG. 6b. The third embodiment is actually a modification of the first and the second embodiments, with FIG. 6a analogous to FIG. 1 and FIG. 6b analogous to FIG. 4. As in the first and second embodiments, the device of this embodiment comprises porous matrix 601 with channels filled with photoactive material 602 and the collecting electrodes 603 and 604. The device is shown with electric load 605 connected between the collecting electrodes In the previously described embodiments the field was produced by material comprised of persistent polarization of dipole moieties that are distributed throughout the field inducing component. In this, the third, embodiment (and in other embodiments to be described herein below) the field is produced by a “frozen” charge spatial distribution 606. In the figures the localized concentration of positive electric charges is located in a thin layer just beneath the bottom surface of matrix 601 (closest to electrode 604) and the concentration of negative electric charges is located in a thin layer just beneath the top surface of matrix 601 (closest to electrode 603). The manufacturing of the device will not be described herein but the differences between the third embodiment and the first and the second embodiments will be emphasized.

In the third embodiment the material of the field inducing component should be able to absorb and to keep injected charges for a long period of time (instead of persistent polarization). This technology has been known for a long time and is used to manufacture the membranes for so called electrets microphones. Organic materials that are suitable for the field inducing component are, for example, polycarbonate or PMMA. SiO₂ and SiN can be named as examples of suitable inorganic materials. The injection of the charges into the materials of field inducing component is performed by the well-known corona charging process.

As an example of a method of manufacturing a device according to the third embodiment, a modification of the manufacturing method of the second embodiment (shown in FIGS. 5a to 5f) can be chosen. All steps of the method are as described herein above with the exception of the step shown in FIG. 5d, i.e. the step of filling the free space of the spatial structure 504 with the field inducing material. In this case, corona-charging process is used to form the field inducing component 505.

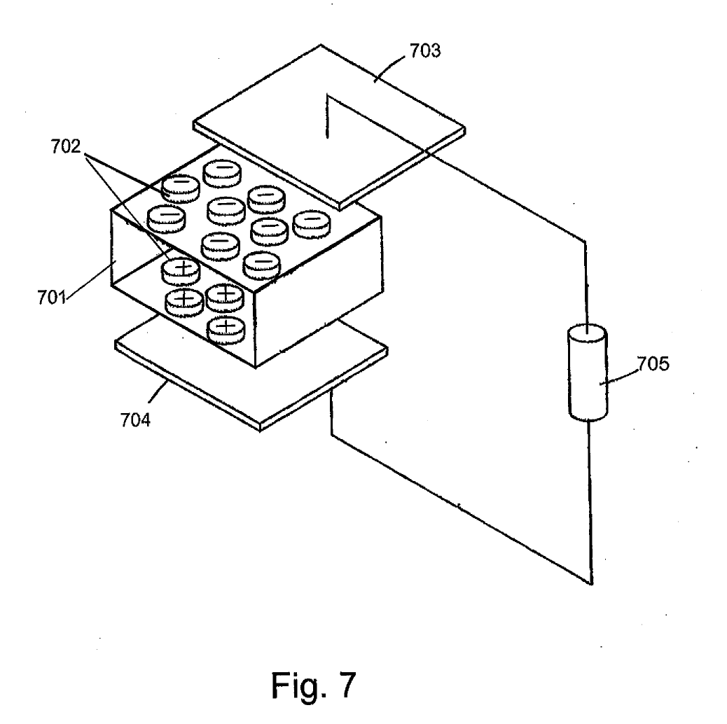

A fourth embodiment of the photovoltaic device of the invention is schematically illustrated in the FIG. 7. In this embodiment the photoactive component is a slab of photoactive material 701. The field-inducing component 702 consists of a plurality of discrete deposits or “isles” of insulating material or of thin porous insulating layers distributed on the surfaces of the slab of photoactive material 701 adjacent to the electrodes The deposits or layers comprise “frozen” electrical charges wherein the charges on the top and bottom of the slab have opposite signs. An external electrical load 705 is connected to the collecting electrodes 703 and 704. There must be electrical continuity between the collection electrodes 703 and 704 and the photoactive component 701 through the spaces between the isles or pores in the layers of field-inducing component 702. Non-limiting examples of spatial dimensions could be as follows: photoactive material slab thickness 0.5-5 micron, thickness of the field-inducing component 100-150 nm, characteristic isle size 100 nm, characteristic distance between the isles 100-150 nm.

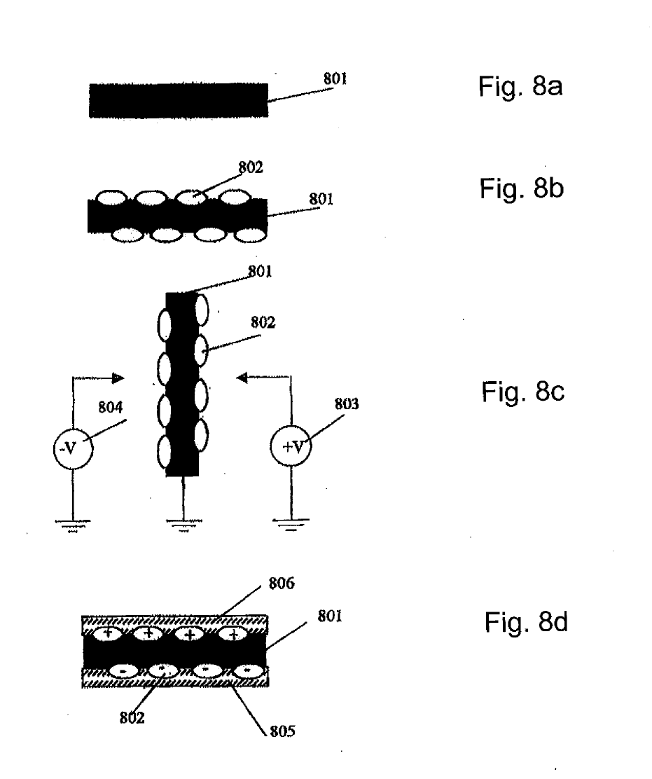

A manufacturing path for the device shown in FIG. 7 that is useful with inorganic photoactive material is schematically illustrated in FIG. 8a to FIG. 8d.
The manufacturing starts from a free-standing layer of the photoactive material 801 (FIG. 8a). The layer may be produced by a variety of methods. For example, a Si layer may be manufactured by electrochemical deposition on sacrificial substrate [see for example, “Electrochemical reduction of silicon chloride in a non-aqueous solvent” Y. Nishimura, Y. Fukunaka, Electrochimica Acta, Vol. 53, pp. 111-116(2007)]
The second step is to produce field-inducing component 802 layer on the surfaces of slab 801 (FIG. 8b). This layer may be manufactured by using evanescent wave nano-lithography or block-copolymer lithography to create a structure, e.g. an array of pits, on the surface with subsequent deposition of the field inducing component material into the created structure or by depositing material 802 directly on the surface of 801. Another method that may be useful for use with a Si slab is a nano-anodization method for producing isles of SiO2 on the Si slab described by Yokoo and Namatsu [“Nanoelectrode lithography”, A. Yokoo and H. Namatsu, NTT Technical Review].
In the next step the field-inducing layers 802 are charged by a corona-charging process (FIG. 8c). Wherein opposite sides of the slab 801 are charged with charges of opposite signs, i.e. the coronas are produced by high-voltage sources 803 and 804 having opposite signs.
Finally the collecting electrodes 805 and 806 are applied by any appropriate method providing electrical connection between the collecting electrodes and the photoactive component material 801 (FIG. 8d).

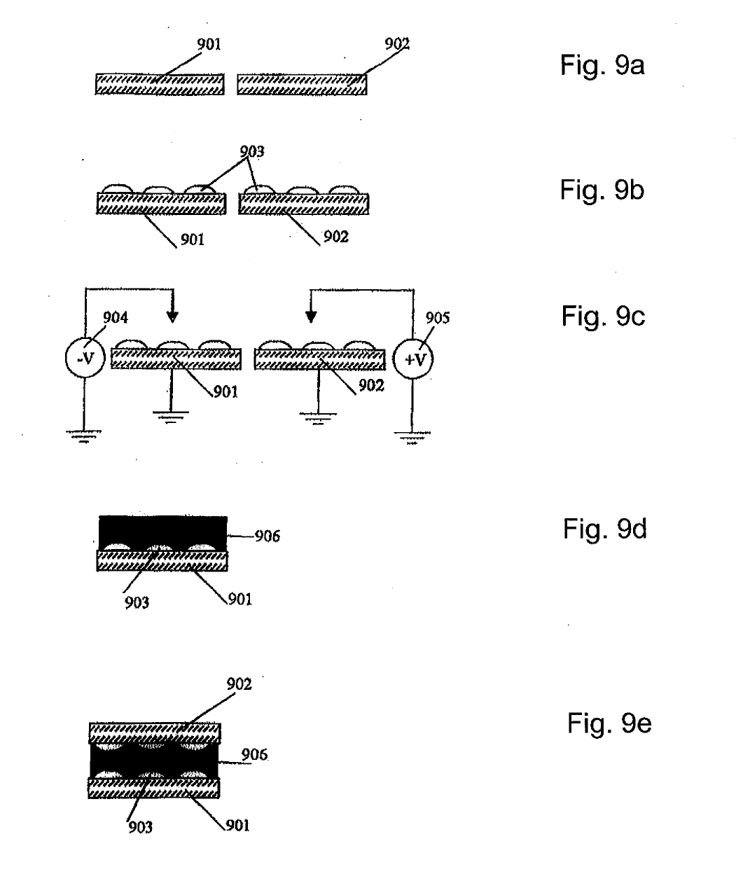

FIG. 9a to FIG. 9e schematically illustrate a manufacturing path for the device shown in FIG. 7 that is useful with polymeric photoactive material or photoactive material that is deposited from solution or melted phase deposition.
The method begins with the collecting electrodes 901 and 902 (FIG. 9a).
The second step is to produce the field inducing component 903 on both collecting electrodes (FIG. 9b). The layer may be manufactured by etching the surface of the electrodes 901 and 902 using evanescent wave nano-lithography or block-copolymer lithography with subsequent deposition of the field inducing component material into the etched structure or by depositing the material of the field inducing component 903 directly on the surfaces of 901 and 902.
In the next step the field inducing layers are charged by a corona-charging process (FIG. 9c). Since the field inducing component on the opposing electrodes should be charged with charges of opposite signs, the coronas are produced by high-voltage sources 904 and 905 having opposite signs.
The photoactive material layer 906 is then deposited above one of the collecting electrodes by simple spin-coating (FIG. 9d).
Finally the second collecting electrode is applied on the photoactive material layer (FIG. 9e).

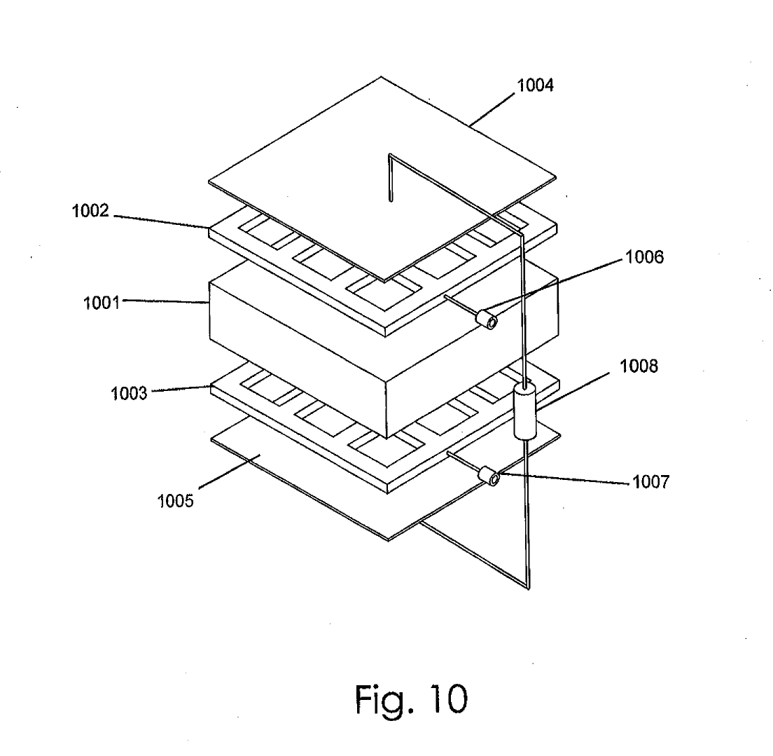

FIG. 10 is an exploded view that schematically shows the fifth embodiment of the photovoltaic device of the invention. The photoactive component of the device consists of a slab of photoactive material 1001 and the field inducing component consists of two grids 1002 and 1003 of conducting material insulated by non-conducting cladding that are located on both sides of the slab 1001. Two collecting electrodes 1004 and 1005 are electrically connected to the slab of photoactive material 1001 through the voids in the grids 1002 and 1003. The grids 1002 and 1003 are made of thin plates of conducting material with an array of holes punched through them and then coated with an electrically insulating material. In electrical contact with the conducting material of which they are made, grids 1002 and 1003 have respective electrical connectors 1006 and 1007 for connection to high voltage sources outside the device. Electrical connectors 1006 and 1007 are electrically insulated from the collecting electrodes and photoactive material. The device is shown with electric load 1008 connected between the collecting electrodes Typical illustrative spatial dimensions and materials are identical to those used in the fourth embodiment of the invention described herein above.

In order to make the device shown in FIG. 10 operational the conducting insulated grids 1002 and 1003 should be connected to opposite poles of an external high voltage source by means of electrical connectors 1006 and 1007. After the grids are charged with charges of opposite signs the high-voltage source is disconnected from them. Charges on the grids produce the electric field in the photoactive component, i.e. the slab 1001 of photoactive material.

The key technological requirement of the present embodiment is the production of the grids of insulated conductors. The critical requirements relate to the spatial dimensions and connectivity. The dimensions must be as follows: thickness on the order of 10-100 nm, characteristic diameter of the voids 10-100 nm, inter-void distance on the order of their diameter.

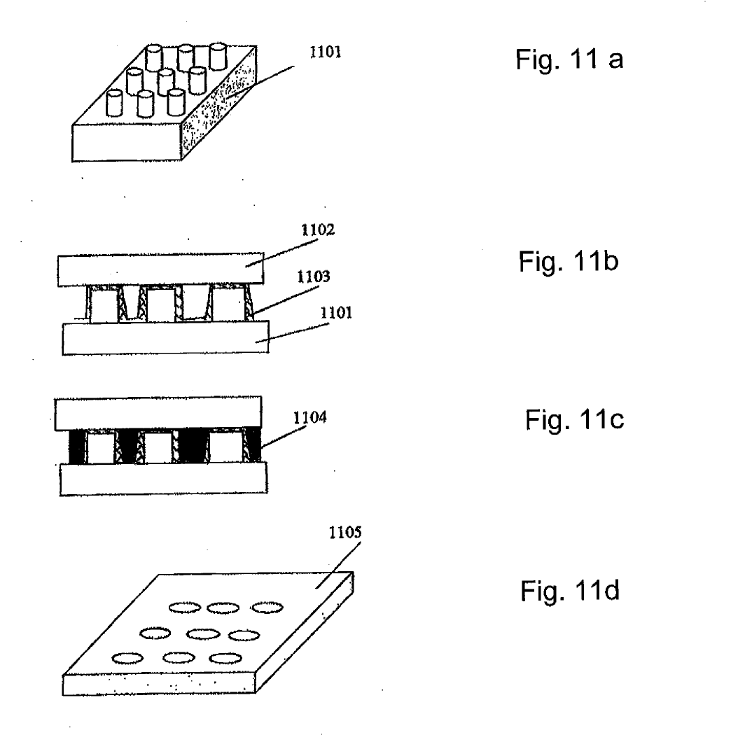

An example of a manufacturing path for fabricating the grids of the device of FIG. 10 is schematically depicted in FIG. 11a to FIG. 11d. This method, which uses detachable forms for electrochemical deposition, comprises the following steps:
In the first step the top surface of a polymeric or inorganic slab is etched away to form a slab 1101 patterned with an array of posts on it top surface (FIG. 11a).
In the second step another slab 1102 with a smooth surface is pressed against the tops of the posts on slab 1101. Prior to pressing the two slabs together an additional sacrificial or detaching-promoting layer 1103 may be applied between the surfaces (FIG. 11b).
Next (FIG. 11c) conducting material 1104, e.g. metal, conducting oxide, or doped semiconductor, is deposited in the voids of the structure produced by the two contacting slabs (patterned 1101 and un-patterned 1102) by any appropriate method. For example, the metal can be deposited by electrolysis.
After the deposition of conducting material 1104 the slabs are detached or dissolved leaving remaining the conductor grid 1105 as a freestanding structure (FIG. 11d).
Finally the freestanding conductor grid 1105 is covered by an electrically insulating mater. For example, an insulating perylene layer can be deposited by chemical vapor deposition

In order to make the process continuous the slabs may be mounted on two opposed cylinders.

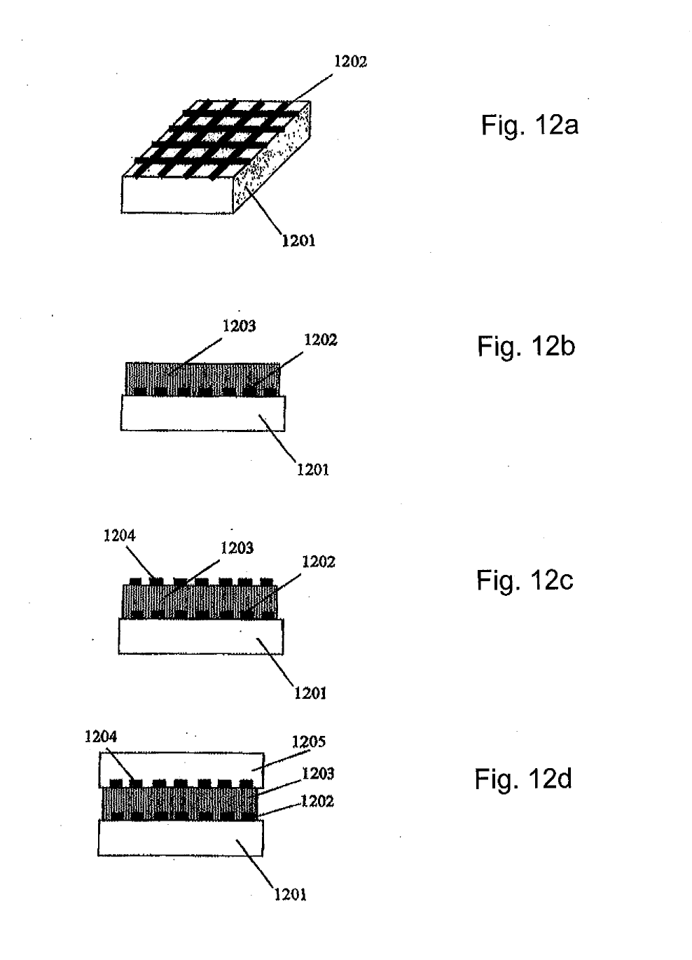

An example of a manufacturing path for fabricating the device of FIG. 10 is schematically depicted in FIG. 12a to FIG. 12d. The steps of this method are:
The manufacturing of device of FIG. 10 starts by covering one of the collecting electrodes 1201 with an insulated grid of conductors 1202 (FIG. 12a). The grid 1202 may have been manufactured by the method described with respect to FIG. 11a to FIG. 11d. For better adhesion of the grid to the electrode special measures such as heating the substrate may be taken.
In the second step any appropriate method is used to deposit the photoactive component in the form of a slab of photoactive material 1203 over the grid 1202 on the collecting electrode 1201 (FIG. 12, b). For example, polymer photoactive material may be deposited by spin-coating from solution, while inorganic material such as Si may be deposited by an electrochemical method as described herein above.
The second grid 1204 is then adhered to the surface of the photoactive component 1203 (FIG. 12 c)
Finally the manufacturing of the device is completed by deposition of the second collecting electrode 1205 on top of the grid 1204 by any of the previously mentioned methods for contact deposition (FIG. 12d).

Although embodiments of the invention have been described by way of illustration, it will be understood that the invention may be carried out with many variations, modifications, and adaptations, without exceeding the scope of the claims. For example, instead of using a sacrificial structure alternative shaping techniques such as nano-embossing or multi-step deposition techniques can be used to produce additional insulation between the components or to produce lateral variation in the structure of the photoactive or field inducing components.

1. A photovoltaic device configured as a sandwiched structure comprising a bulk region between a pair of collecting electrodes, said bulk region comprising a matrix portion and a host portion; wherein either said matrix portion or said host. portion is comprised of an electric-field inducing component and the remainder of said bulk region is comprised of a photoactive component; wherein said photoactive component is in electric contact with both of said collecting electrodes to provide a continuous conduction path for photo-generated charge carriers between said electrodes; wherein said electric-field inducing component does not participate in transport of said photo-generated charge carriers; wherein said electric-field inducing component is adapted to provide a permanent electric field having high electric strength in the entire inter-electrode region, thereby inducing an electric field in said photoactive component.

2. The photovoltaic device of claim 1, in which an electrical current flows through said device and a load electrically connected to the collecting electrodes when the photoactive component is illuminated and/or irradiated.

3. The photovoltaic device of claim 2, in which the photoactive component is illuminated and/or irradiated by at least one of the following: electro-magnetic radiation; the sun; decay of the nucleus of a radioactive material; and a photo-chemical reaction.

4. The photovoltaic device of claim 1, in which the bulk region is provided with a plurality of through going channels that are filled with the host portion.

5. The photovoltaic device of claim 4, in which the channels are rectilinear and parallel to each other.

6. The photovoltaic device of claim 4, in which the channels are curvilinear and are chaotically distributed within the bulk region, wherein said channels are interconnected such that, although an individual channel may not pass entirely through said bulk region, it will intersect another channel or channels such that there is a continuous open path from the end of a given channel that is open on one of the electrodes to the other electrode.

7. The photovoltaic device of claim 1, comprising collecting electrodes made from electrically conductive material selected from the group comprising: metals, semiconductors, conductive polymers, conductive oxides and their combinations.

8. The photovoltaic device of claim 1, comprising a photoactive component made from photoactive material selected from the group comprising: semiconductors of group IV of the periodic table, group III-V semiconductors, group II-VI semiconductors, photoactive polymers and their combinations.

9. The photovoltaic device of claim 1, comprising electric-field inducing components that are comprised of materials that retain sustained polarization.

10. The photovoltaic device of claim 9, wherein the material of which. the electric-field inducing components are comprised is selected from the group comprising: ferroelectric materials and polymeric ferroelectrics.

11. The photovoltaic device of claim 1, comprising electric-field-inducing components comprising a plurality of dipole moieties that are capable of being polarized and retaining orientation of the induced polarization.

12. The photovoltaic device of claim 11, in which the dipole moieties are selected from the group consisting of organic dielectric materials, inorganic dielectric materials, and their combinations.

13. The photovoltaic device of claim 12, wherein the inorganic dielectric materials are selected from the group of materials having formula SiOₓ, SiNₓ, and their combinations.

14. The photovoltaic device of claim 1, comprising electric-field inducing components comprising a material capable of retaining spatial charge distribution.

15. The photovoltaic device of claim 11 wherein the photoactive component is a slab of photoactive material and the field-inducing component consists of a plurality of isolated deposits of insulating material or of thin porous insulating layers, said deposits or layers comprising “frozen” electrical charges and distributed on the surfaces of the slab of photoactive Material adjacent to the electrodes.

16. The photovoltaic device of claim 11, wherein the photoactive component is a slab of photoactive material and the field-inducing component comprises at least one electrically conductive grid having a plurality of openings, said grid being located between a surface of said slab of photoactive material and at least one collecting electrode; said grid being electrically insulated from said photoactive material and from the adjacent collecting electrode.
